(19) United States
(12) Patent Application Publication
(10) Pub. No.: US 2001/0037770 A1
(43) Pub. Date: Nov. 8, 2001

(54) Plasma processing apparatus and processing method

(76) Inventor: Toru Otsubo, Fujisawa (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/842,000

(22) Filed: Apr. 26, 2001

(30) Foreign Application Priority Data
Apr. 27, 2000 (JP) 2000-128481

(51) Int. Cl. H01L 21/302

(52) U.S. Cl. 118/723 I; 156/345; 438/710

(57) ABSTRACT

The present invention controls the state electronic energy and generation of radical species by controlling the electron energy state using electromagnetic wave radiated into plasma and magnetic field, and by controlling each state of capacitatively coupled discharge, inductively coupled discharge and electronic cyclotron resonant discharge. The present invention further controls radiated electromagnetic wave power distribution through displacement current control, and controls uniformity in plasma processing through plasma distribution control. Still further, it controls the density distribution of radio frequency current flowing through the substrate, thereby preventing changes in characteristics of semiconductor devices.

### BACKGROUND OF THE INVENTION

1. Field of the Invention

The present invention relates to a plasma processing apparatus equipped with a plasma generation means and plasma processing method, or especially to plasma etching suited to formation of the minute pattern of a semiconductor device and liquid crystal display device and uniform processing of a large-diameter substrate, plasma CVD suited to formation of a thin film having a minute structure, plasma processing apparatus for plasma polymerization, and plasma processing method.

2. Related Background Art

In the plasma processing apparatus which processes a semiconductor device and liquid crystal display device using plasma, it is required that the electric characteristics of the semiconductor device is not changed by control and treatment of the radical species affecting the processing performance, energy and directionality of ion applied to the substrate to be processed, and uniformity in plasma processing.

Regarding the control of radical species generation, Official Gazette of Japanese Patent Laid-Open NO. 195379/1996 discloses a plasma processing method characterized by excellent radical species generation controllability is realized by generation of plasma containing both capacitatively coupled and inductively coupled characteristics.

Ion energy control and ion directionality are mentioned in the Official Gazette of Japanese Patent Laid-Open NO. 158629/1985, which discloses a method of electronic cyclotron resonant discharge and application of radio frequency bias to a substrate supporting electrode. Official Gazette of Japanese Patent Laid-Open NO. 206072/1993 reveals a method of inductively RF coupled discharge and application of radio frequency bias to a substrate supporting electrode. These methods have realized improvement of directionality of ion by generation of high density plasma at a low pressure and ion energy control by application of radio frequency bias.

Regarding uniformity control, Official Gazette of Japanese Patent Laid-Open NO. 195379/1996 discloses that a plasma processing technique featuring excellent controllability of plasma density distribution is realized by generation of plasma containing both capacitatively coupled and inductively coupled characteristics.

Furthermore, regarding the control of plasma processing uniformity, the Official Gazette of Japanese Patent Laid-Open NO. 283127/1986 discloses the art where the electrode to which radio frequency power is applied is split into multiple pieces, and power applied to each electrode is independently controlled, thereby improving uniformity.

Official Gazette of Japanese Patent Laid-Open NO. 260596/1999 reveals the art of controlling plasma density distribution by controlling the electromagnetic wave emission distribution.

One of the problems in treating a semiconductor device substrate using plasma is that electrical characteristics of the semiconductor device is changed by electrical influence during plasma processing. Official Gazette of Japanese Patent Laid-Open NO. 3903/2000 shows an art of reducing influence of plasma processing upon electric characteristics.

To satisfy processing characteristics required for production of a semiconductor device and liquid crystal display device, mere ion energy control is not sufficient. Processing characteristics are greatly affected by radical species, and its general control method is to change the processing conditions such as plasma generating radio frequency power and pressure in the process chamber.

However, radical species control based on processing conditions is limited, and differences in processing performances cannot be covered merely by changing the processing conditions if the dischargemethod is different, as in the case of the electronic cyclotron resonant method, inductive RF coupled method, and most popular parallel plate electrode method mentioned as prior arts.

Thus, problems remain that processing performances realized by parallel plate electrode method cannot be realized by electronic cyclotron resonant method, inductively RF coupled method, etc.

The electronic cycrotron resonant method allows effective acceleration of electrons to be achieved by resonance. So electron energy level is high, and processing is difficult when decomposition of process gas is reduced. In the inductively RF coupled method, plasma of locally high density is formed by electromagnetic waves radiated from the antenna, and is diffused upward. So electron energy level at plasma generating portion is high, and processing is difficult when decomposition of process gas is reduced.

In the parallel plate method, by contrast, electron is accelerated on the sheath formed on the electrode surface and interface of plasma and energy level is low. So this method is suited to processing under the condition where process gas decomposition is reduced.

As described above, electron acceleration mechanism in plasma is different depending on the discharge method, and this is the reason why the differences in performances of each method cannot be covered by processing conditions.

Another problem is how to ensure uniform processing of all the substrates. To improve productivity, the diameter of the substrate to be processed has been increased from 150 mm to 200 mm, and the diameter tends to increase to 300 mm. According to the prior art, uniformity has been achieved by changing the processing conditions or by taking such similar means.

However, change of processing conditions is insufficient, as described above, but this is one of the important means to control the radical species. This makes it necessary to ensure a uniformity control means which ensures compatibility between processing conditions which implement optimum etching characteristics and film formation characteristics and uniformity in processing.

The prior arts revealed in said Official Gazette of Japanese Patent Laid-Open NO. 195379/1996 and Official Gazette of Japanese Patent Laid-Open NO. 283127/1986 are not sufficient in mutual independence between uniformity in plasma processing and control of radical species generation, and compatibility between uniformity control and low pressure processing. Furthermore, a plasma density distribution control method disclosed in the Official Gazette of Japanese Patent Laid-Open NO. 260596/1999 is not sufficient in plasma distribution control range. These are the problems of the prior arts.

Electric characteristics conductor devices change when plasma is used to process these semiconductor device substrates due to the electric influence during plasma processing. This problem is caused by uneven self-bias potential occurring to the sheath between the substrate under processing and plasma.

To control ion energy, radio frequency power is applied to the substrate supporting electrode. One of the major reasons for uneven self-bias potential is that radio frequency current distribution resulting from application of this radio frequency power becomes uneven on the substrate.

The self-bias potential control method disclosed in said Official Gazette of Japanese Patent Laid-Open NO. 3903/2000 cannot control the self-bias potential distribution, and is insufficient to reduce the changes in electric characteristics.

Furthermore, higher integration of semiconductor devices and greater diameter of the substrate for production have made it necessary to develop a technique providing a better controllability than prior arts, e.g. higher selectivity with underlying material, higher performance in processed shapes, more uniform processing of large-diameter substrates, and less influence upon device characteristics.

Regarding uniformity in plasma processing, the following trend is observed: As a result of increased diameters of the substrates to be processed, the process gas for etching and CVD processing flows from the center of the substrate to the outer periphery, and radical species concentration distribution and deposition film distribution become apparent. This makes it difficult to ensure uniform processing on all surfaces of the large-diameter substrate.

To solve these problems, the factors disabling uniform distribution must be offset by other etching characteristic controlling factors. One of the controlling factors is the capability of adjusting plasma distribution as a convex/concave distribution, independently of processing conditions such as plasma generation power and pressure.

Radical species is generated by collision between process gas and electron in plasma, and is one of the factors which greatly affect the processing characteristics such as selectivity, processed shape and film quality in etching and CVD processing by plasma. The generated volume and type of this radical species is determined by the status of energy of electrons in plasma.

Furthermore, to protect against the influence of plasma processing upon semiconductor device, distribution of the RF current flowing through the substrate must be controlled in order to control self-bias potential distribution.

### SUMMARY OF THE INVENTION

One of the object of the present invention is to realize a plasma processing apparatus and processing method which have a wide control range for the status of electron energy, independently of processing conditions and uniformity control, and which are capable of controlling radical species generation.

Another object of the present invention is to realize a plasma processing apparatus and processing method comprising a uniformity control means capable of controlling independently of processing conditions such as plasma generation power and pressure, said uniformity control means providing compatibility of plasma uniformity with radical species control, ion energy control and improved ion directionality by generation of low pressure/high density plasma.

A further object of the present invention is to realize a plasma processing apparatus and processing method comprising a means of controlling the distribution of RF current flowing through the substrate, said means providing compatibility among plasma uniformity, radical species control, ion energy control and improved ion directionality.

To achieve said objectives, the present invention has the following arrangement:

(1) A plasma processing apparatus comprises a plasma processing gas supply means, an exhaust means in a plasma process chamber, a plasma generating means, and a means to process plasma using the generated plasma; said plasma generating means characterized by further comprising an electromagnetic wave radiating means by displacement current and magnetic field forming means. Said electromagnetic wave radiating means further comprises a means of controlling the radio frequency displacement current flowing between the conductors by forming from each of multiple insulated conductors the electrode of said capacitatively coupled discharge means to which RF voltage is applied.

(2) A plasma processing apparatus comprises a plasma processing gas supply means, an exhaust means in a plasma process chamber, a plasma generating means, and a means of applying RF power to control the energy of ion applied to the substrate placed on the stage, wherein the facing electrode through which RF power current due to said radio frequency power flows via plasma is composed of multiple insulated conductors, and a means is provided to make variable the impedance between these conductors and ground.

(3) A plasma processing apparatus comprises a plasma processing gas supply means, an exhaust means in a plasma process chamber, a plasma generating means, and a means of applying RF power to control the energy of ion applied to the substrate placed on the stage. Said plasma processing apparatus further comprises a stage for applying said radio frequency power and a means of keeping the facing electrode separated from the ground, wherein RF current due to application of radio frequency power flows through said facing electrode via plasma.

(4) For uniformity, plasma distribution is controlled by controlling the distribution of the radiated electromagnetic wave power and controlling the radio frequency power supplied to plasma in a capacitatively coupled state from multiple conductors to which radio frequency power is applied.

The mechanism of giving energy to the electron in plasma from electric field of electromagnetic wave includes a method of direct acceleration in the electric field of electromagnetic wave by increasing electromagnetic wave power (IPC: inductively coupled plasma). Another method included in said mechanism is to accelerate electrons by matching between the direction in which electrons are rotated by the magnetic field and the direction of the electric field of electromagnetic wave by application of magnetic field (electron cyclotron resonance).

Energy is supplied by the former method when magnetic field is not applied. When magnetic field is applied, electromagnetic wave passes through plasma more easily, and energy is supplied by the latter method.

When magnetic field is applied, the direction of electron motion is matched with the direction of the electric field of electromagnetic wave, if the frequency at which electrons are rotated by magnetic field are matched with the frequency of electromagnetic wave (electron cyclotron resonant conditions). Accordingly, electrons are kept accelerated until they collide with gas molecules, thereby creating high energy. If magnetic field conditions disagree with electron cyclotron resonant conditions, the direction of electron motion gradually disagrees with the direction of the electric field of electromagnetic wave, and acceleration and deceleration of electrons are repeated.

As the magnetic field conditions disagree with electronic cyclotron resonant conditions, the maximum energy reached by electrons is reduced. Electron energy becomes lower than that under electronic cyclotron resonant conditions.

As described above, control of the magnetic field conditions allows free control of electron energy. This makes it possible to control the generation volume and type of the radical species produced by decomposition of process gas.

In the event of disagreement with resonant conditions, the maximum energy reached by electrons has the following relationship: The percentage of reduction of the maximum energy of electron with respect to the percentage of disagreement of magnetic field conditions with the resonant conditions increases in direct proportion to electromagnetic wave frequency. Under the conditions of 2.45 GHz which is normally used, there is a sharp reduction of electron energy due to deviation from the electronic cyclotron conditions, and practical control is difficult. Practically controllable frequency range is from 200 MHz to 10 MHz.

Electron cyclotron resonance at a frequency of several tens of MHz to 300 MHz is disclosed in Oda, Noda, and Matsumura (Tokyo Institute of Technologies): Generation of Electron Cyclotron Resonance Plasma in the VHF Band: JJAP Vol.28, No.10, October, 1989 PP.1860-1862, and Official Gazette of Japanese Patent Laid-Open NO.318565/1994. The relationship between the state of electron energy and magnetic field strength is not described therein.

A means to emit electromagnetic waves was arranged in such a way that displacement current was fed between insulated conductors and electromagnetic wave is radiated by this displacement current. A resonant circuit having the same resonant frequency as the radio frequency to be applied, including the capacity formed between conductors, was formed between the conductors. Thus, resonant conditions were controlled, thereby controlling the displacement current and radiated electromagnetic wave power.

Multiple RF current conducting means are installed at the position opposite to the position where the substrate to be processed is mounted to ensure that control the RF current ratio flowing through said multiple RF current conducting means.

When there is no magnetic field, electromagnetic wave hardly progress in plasma. Under this condition without magnetic field, conditions close to resonance conditions are setup, and radiated electromagnetic wave power is increased, thereby ensuring energy to be supplied electrons in plasma from electromagnetic wave at a position close to where electromagnetic wave is radiated. Under these conditions, electron energy becomes partially high at a position close to where electromagnetic wave is radiated, and decomposition of process gas proceeds. This makes it difficult to control at the state of low dissociation.

Under the condition where magnetic field is applied, electromagnetic wave is likely to progress in plasma. This allows energy to be supplied from electromagnetic wave into electron in plasma over the entire space where plasma is generated. This leads to uniform distribution of electronic energy. Furthermore, electron energy level is also made low, and control is made in the state of low dissociation.

As under the condition without magnetic field, if energy is supplied at a position close to where electromagnetic wave is radiated, high density plasma is formed in this portion, and diffusion from this position allows plasma to reach the substrate to be processed. In such a mechanism, therefore, diffusion is changed by pressure, and plasma density and plasma distribution on the substrate to be processed is affected by pressure.

By contrast, when magnetic field is applied and energy is supplied over the entire space where plasma is generated, they are not affected by diffusion of plasma. So plasma distribution is not easily affected by processing conditions such as pressure. Such conditions are essential to control processing conditions and plasma distribution independently.

As means of controlling uniformity according to the present invention, multiple portions were provided where electromagnetic wave was radiated by displacement current, and arrangement was made to ensure that the amount of radiated electromagnetic wave could be controlled at least one of said portions. The resonance conditions control method described above is used for this control. The portion radiating electromagnetic waves is provided in a double configuration to have a circular form, then plasma distribution can be controlled as a convex/concave distribution by controlling each radiated electromagnetic wave.

Furthermore, when the magnetic field is applied, plasma is generated over the entire plasma generation space. Then changes of plasma distribution are less often caused by processing conditions, and plasma distribution control by control of resonance conditions can be made independently of processing conditions. Also, the generated volume and type of the radical species can be controlled by magnetic field, independently of the uniformity control and processing conditions.

If the conductor portion radiating electromagnetic waves is provided close to plasma, power can be supplied to plasma by capacitative coupling. Therefore, in the present invention, discharge can be made by the same capacitative coupling as that of the parallel plate electrode method under the conditions where resonant circuit current is reduced without magnetic field being applied. Inductively coupled discharge due to electromagnetic wave emission is caused by increasing the resonant circuit current, and discharge under electron cyclotron resonance conditions can be caused by application of magnetic field.

Capacitatively coupled discharge, inductively coupled discharge and electronic cyclotron discharge each have different states of electron energy and different states of process gas decomposition. The present invention allows radical species to be controlled by controlling the discharge method, in addition to radical species control by magnetic field described above.

The energy of the ion applied to the substrate placed on the stage is controlled by application of radio frequency power. Radio frequency current by this radio frequency power is fed to the facing electrode through plasma.

To solve the problem that electric characteristics of the semiconductor device is changed by electric influence during plasma processing, this facing electrode is composed of multiple insulated conductors, and the radio frequency current flowing through the substrate mounted on the stage is made uniform by optimization of impedance between these conductor and ground. This has ensured uniform distribution of self-bias potential on the substrate, and has reduced changes in electric characteristics of the semiconductor device resulting from electric influence during plasma processing.

Also, the stage and facing electrode through which radio frequency current flows via plasma are kept separated from the ground. This greatly reduces the percentage of radio frequency current flowing from the stage into plasma by application of radio frequency power, with respect to that flowing to the conductor connected to the ground other than facing electrode.

This allows almost all radio frequency currents to flow between the stage and facing electrode. Also, radio frequency current on the stage can be made uniform by installing the facing electrode parallel with the stage. This can reduce changes in electric characteristics of the semiconductor device resulting from electric influence during plasma processing.

### BRIEF DESCRIPTION OF THE DRAWINGS

FIG. 1 is a schematic drawing representing a plasma processing apparatus in the first Embodiment according to the present invention;

FIG. 2 is a drawing representing a resonant circuit model in the first Embodiment according to the present invention;

FIG. 3 is a drawing representing a plasma density distribution control in the first Embodiment according to the present invention;

FIG. 4 is a drawing representing a plasma density distribution control in the first Embodiment according to the present invention;

FIG. 5 is a drawing representing a plasma density distribution control in the first Embodiment according to the present invention;

FIG. 6 is a drawing representing the relationship between variable capacitor capacity and plasma density distribution uniformity in the first Embodiment according to the present invention;

FIG. 7 is a drawing representing a radio frequency current path model based on application of radio frequency bias in the prior art;

FIG. 8 is a drawing representing a radio frequency current path model based on application of radio frequency bias in the first Embodiment according to the present invention;

FIG. 9 is a drawing representing the arrangement of a cover member in the first Embodiment according to the present invention;

FIG. 10 is a schematic drawing representing a plasma processing apparatus in the second Embodiment according to the present invention; and

FIG. 11 is a schematic drawing representing a progress of etching in the second Embodiment according to the present invention.

### DETAILED DESCRIPTION OF PREFERRED EMBODIMENTS

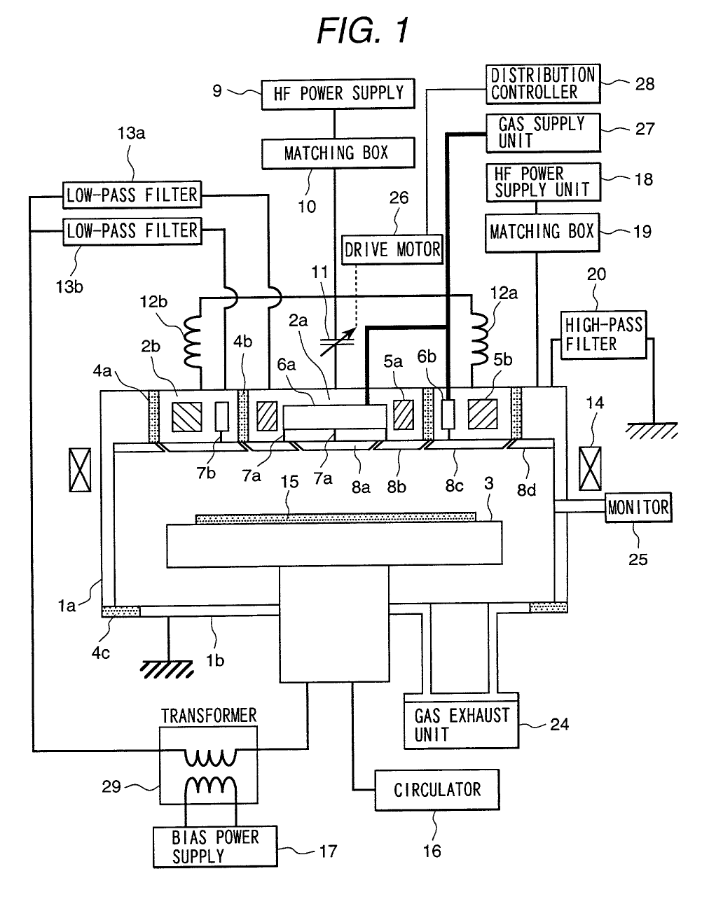

One Embodiment of the present invention will be described with reference to the attached drawings. FIG. 1 is a schematic drawing of a plasma processing apparatus as the first Embodiment.

A process chamber 1 comprises inner wall surfaces 1a and 1b, and both inner wall surfaces are insulated by a insulator 4c. Facing electrode 2a and 2b and stage electrode 3 are placed therein face to face with each other. They are insulated from a facing electrode 2b by an insulator 4a, and from a stage electrode 3 by the insulator (not illustrated). The facing electrodes 2a and 2b are insulated from each other by an insulator 4b.

Connections between the inner wall surface of the process chamber 1, electrode and insulator are vacuum sealed. Refrigerant flow paths 5a and 5b, and process gas supply paths 6a and 6b are provided inside the facing electrode. Refrigerant flow paths 5a and 5b are connected to the circulator (not illustrated) to ensure that the facing electrode temperature can be kept at the set value.

Process gas supply paths 6a and 6b are connected to the process gas supply source 27 so that process gas of the set flowrate can be supplied. Covers 8a, 8b, 8c and 8d are mounted on the surface of the facing electrode, and each cover has a space of 0.2 mm.

Process gas is supplied to the back of covers 8a, 8b and 8c through gas inlets 7a and 7b from process gas supply paths 6a and 6b. Passing through the 0.2 mm space between covers, it is fed to the process chamber 1.

The inner wall surface la is connected with a radio frequency power supply 18 and matching box 19. It is also connected with a high pass filter 20 in conformity to frequency of the radio frequency power supply 9, so that radio frequency current from radio frequency power supply 9 is fed to the ground.

Facing electrode 2a is connected with radio frequency power supply 9 through matching box 10 and variable capacitor 11, and facing electrode 2b is connected with radio frequency power supply 9 through matching box 10 and inductors 12 and 12b.

Facing electrodes 2a and 2b are connected with low pass filters 13a and 13b in conformity to the frequency of bias power supply 17 so that radio frequency current from the bias power supply 17 applied to the stage electrode 3 can be fed to a transformer 29 through facing electrodes 2a and 2b.

A coil 14 is provided on the outer periphery of the process chamber 1 so that magnetic field intersecting at right angles with the facing electrodes 2a and 2b is formed in the process chamber.

A substrate 15 can be mounted on a stage electrode 3. It is chucked on the surface of a stage electrode 3 by the electrostatic chucking unit (not illustrated), and refrigerant is supplied from a circulator 16 to a temperature controller (not illustrated) to permit control of the temperature of the substrate 15 during plasma processing.

Furthermore, a stage electrode 3 is connected with a bias power supply (2 MHz) 17 through transformer 29 in order to control the energy of ion applied to the substrate during plasma processing. A transformer 29 is kept separated from the ground to reduce capacitive component with the ground. The outer periphery of the stage electrode 3 is composed of a member connected to the ground.

The interior of the process chamber 1 is arranged to be exhausted to the state of vacuum by an exhaust controller 24 and exhausting capacity can be adjusted and pressure can be adjusted to the set value. A monitor 25 is installed in the process chamber 1 to monitor the progress of plasma processing.

A variable capacitor 11 has its capacity value controlled by a drive motor 26 controlled by distribution controller 28.

The following describes an example of example in etching as the first Embodiment of the present invention: A substrate 10 is inserted into the stage electrode 3, and is placed therein. Etching gas (carbon fluoride based gas) of the set flowrate is fed from an etching gas supply source 27, and exhaust is controlled so that pressure in the process chamber will be 1 Pa.

Etching gas is supplied to the back of covers 8a and 8b from process gas supply paths 6a and 6b through gas inlets 7a and 7b. To feed gas to the process chamber 1 through the 0.2 mm space between covers, the pressure on the back of covers is increased and covers are cooled by facing electrodes 2a and 2b.

Silicon oxide film as an insulator of semiconductor device and silicon film are formed on the substrate. This substrate is electrostatically sucked on the stage electrode 3, and helium gas is supplied between the substrate and stage electrode 3 from a helium gas supply source (not illustrated), thereby reducing thermal resistance from the substrate to the stage electrode 3 and avoiding rise of temperature in the substrate being etched.

From the radio frequency power supply 9, 100 MHz, 2000 W radio frequency power is applied to the facing electrodes 2a and 2b, and plasma is generated by capacitatively coupled discharge.

Firstly, the following describes the principle of emission of electromagnetic wave from the outer periphery of the insulator 4a:

When radio frequency power is supplied to the facing electrode, radio frequency potential occurs to the facing electrode 2b. Since inner wall surface 1a is connected to the ground through a bypass filter, radio frequency displacement current flows to the facing electrode 2b and inner wall surface 1a. This displacement current is fed through the insulator 4a, so electromagnetic wave is radiated by this radio frequency displacement current, and electromagnetic wave is radiated into the process chamber 1 through the space between the covers 8c and 8d.

Next, emission of electromagnetic wave from the insulator 4b on the inner periphery will be explained.

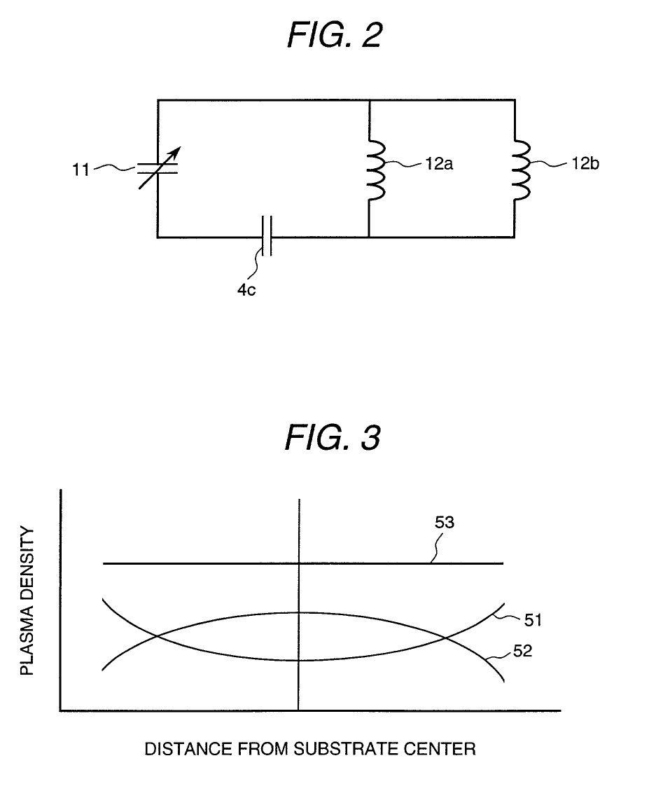

The insulator 4b between facing electrodes 2a and 2b is formulate into a model by means of a capacitor. A resonant circuit shown in FIG. 2 is formed by this capacitor 4c, variable capacitor 11, and inductors 12a and 12b.

When the capacity of the variable capacitor 11 comes close to the resonant conditions, a greater amount of radio frequency current flows to this circuit. When the capacity of the variable capacitor 11 fails to meet the resonant conditions, the radio frequency current flowing to this circuit is reduced.

As described above, displacement current flowing to the insulator 4b can control the variable capacitor 11, and electromagnetic wave is radiated in direct proportion to radio frequency displacement current flowing to insulator 4b. Furthermore, electromagnetic wave is radiated into the process chamber 1 through the space between covers 8b and 8c. The electromagnetic wave emission power can be controlled by controlling radio frequency displacement current flowing to the resonant circuit using the capacity of the variable capacitor 11.

The density of the plasma generated from electromagnetic waves radiated from the insulator 4a on the outer periphery exhibits a convex distribution with high outer periphery, similarly to the plasma distribution 51 shown in FIG. 3. Density of the plasma generated electromagnetic waves radiated from the insulator 4b on the inner periphery exhibits a concave distribution with a high central portion, similarly to the plasma distribution 52 shown in FIG. 3.

The overall plasma distribution is obtained by superimposing the distribution of the plasma resulting from electromagnetic wave radiated from this outer periphery over that resulting from electromagnetic wave radiated from the inner periphery. Uniform plasma can be formed by adjusting the power of electromagnetic wave radiated from the inner periphery, where plasma density distribution in the vicinity of the substrate 15 within the range from 300 mm is within±5%, as in the case of plasma density distribution 53.

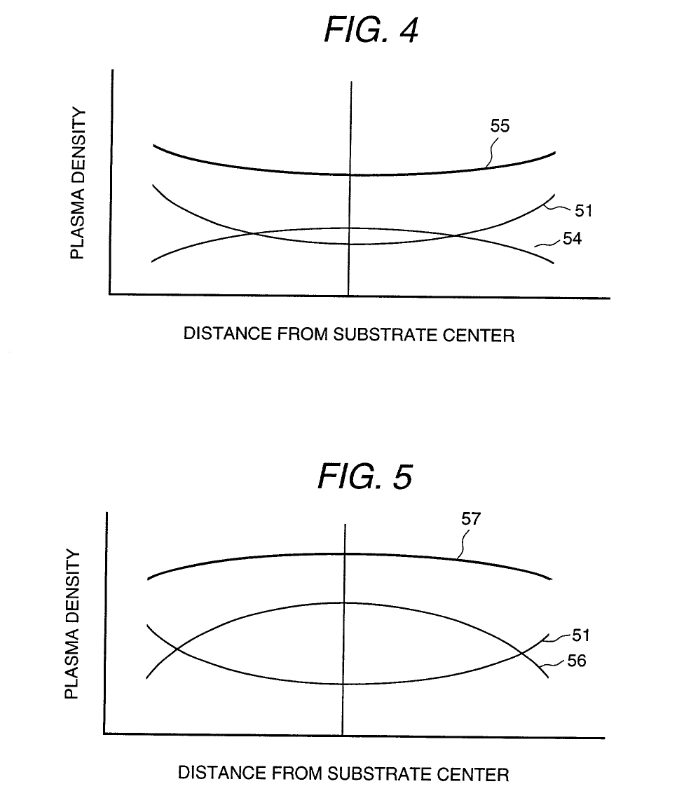

If the power of electromagnetic wave radiated from the inner periphery is reduced, the density of plasma generated from electromagnetic wave radiated from the inner periphery is reduced as in the case of plasma density distribution 54 shown in FIG. 4. Overall plasma density distribution exhibits a convex distribution, as shown in plasma density distribution 55.

If the power of electromagnetic wave radiated from the inner periphery is increased, the density of plasma generated from electromagnetic wave radiated from the inner periphery is increased as in the case of plasma density distribution 56 shown in FIG. 5. Overall plasma density distribution exhibits a concave distribution, as shown in plasma density distribution 57.

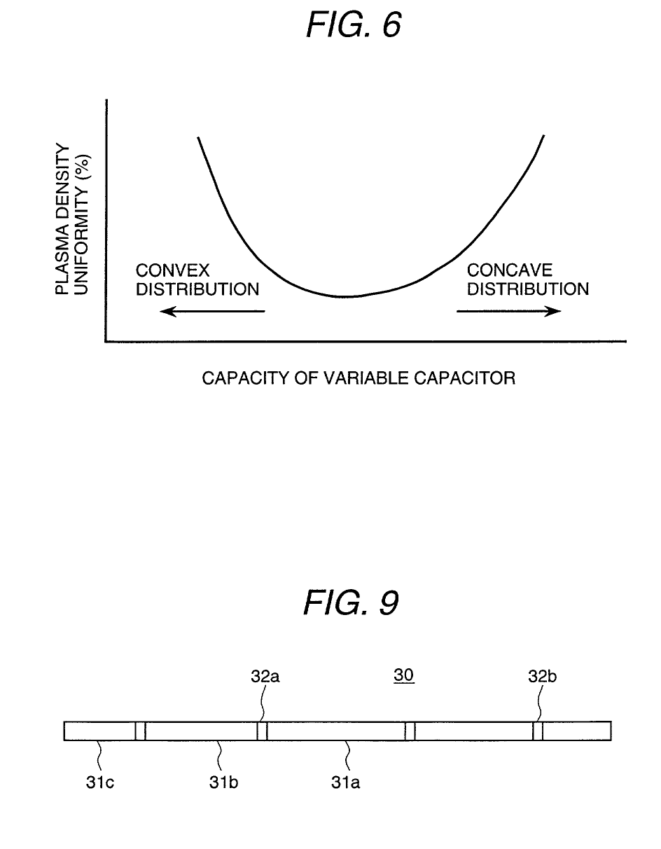

FIG. 6 shows the relationship between the capacity of variable capacitor 11 and uniformity of plasma density. Increase of the capacitor capacity causes plasma density distribution to be changed from convex to flat, then to concave distribution, showing that plasma density distribution can be controlled by the capacity of the variable capacitor 11.

The capacity of the variable capacitor 11 is controlled by control from the distribution controller 28 and drive motor 26. Such control is also possible during etching.

When magnetic field is not formed, electromagnetic wave is reflected by generated plasma, and influence on plasma is small. In this case, discharge is mostly capacitatively coupled discharge, so electron energy distribution of plasma is close to Maxwell-Boltzmann distribution.

When magnetic field is formed, current is fed to coil 14 to form magnetic field. This magnetic field is formed almost in conformity to the direction of said electromagnetic wave emission. In the vicinity where electron cyclotron resonance (35G (35×10⁻⁴T)) is caused by magnetic field strength with respect to the frequency of radiated electromagnetic wave, energy is supplied to electron in plasma more effectively that electromagnetic wave electric field, thereby allowing electron energy to be increased.

At 100 MHz electron cyclotron resonance as in the case of the first Embodiment of the present invention, the rotating angular velocity of the electron is reduced in direct proportion to electromagnetic wave frequency, compared with electron cyclotron resonance due to conventional 2.45 GHz microwave. However, the electric field of the electromagnetic wave accelerating electron remains unchanged if the power density is the same, without depending on frequency. The same energy can be given to electrons.

If frequency is low, angular velocity is reduced, so disagreement between cyclotron frequency due to magnetic field and frequency of electromagnetic wave occurs. This increases tolerance in exchange of energy. In the case of 100 MHz, for example, electrons can be accelerated to the level required for ionization and generation of radical species in a wide range of magnetic field strength from 10G (10×10⁻⁴T) to 70G (70×10⁻⁴T).

In this case, the maximum energy of electrons to be accelerated is reduced with increasing departure from electronic cyclotron conditions, making it possible control the state of electron energy by magnetic field strength. Namely, electron energy can be changed from the level suited to generation of the radical species up to the level of ionization by changing the magnetic field strength.

In the first Embodiment according to the present invention, magnetic field strength is set to 50G (50×10⁻⁴T) which is higher than electronic cyclotron condition. The condition is set to the state where the maximum electron energy is reduced.

Such an effect is measured because electromagnetic wave frequency is within the range from from 200 MHz to 10 MHz. Easy use and excellent effects can be ensured especially within the range from 100 MHz to 50 MHz. If the electromagnetic wave frequency is 200 MHz, the range where there is an effect of controlling the state of electron energy by magnetic field strength is reduced in inverse proportion to the frequency, so this range is up to about 100G (100×10⁻⁴T). In the case of 10 MHz, the effect of magnetic field can be measured when magnetic field strength is about 2G(2×10⁻⁴T) or more.

When 2 MHz radio frequency power of 1000W is supplied to a stage electrode 3 from the bias power supply 17, the voltage of 700Vpp appears, and ion from plasma is accelerated by this voltage. It is applied to substrate 15. Etching gas (carbon fluoride based gas) decomposed by plasma with the aid of ion reacts with silicon oxide film and silicon film on the back of the substrate 15, and etching takes place.

If electron energy level is high, decomposition of carbon fluoride based gas takes place and fluorine based radical species increases in number, resulting in improved etching rate of silicon film. In an advanced state of gas decomposition, the cross section geometry of etching shows an almost vertical shape. If decomposition does not proceed, a forward tapered shape tends to be produced.

In the production of a semiconductor device the etching rate of the silicon film with respect to that of the silicon oxide film as an insulator must be minimized, and the cross section geometry of etching must be made as close as possible to a vertical shape. This requires an adequate control of the decomposition of carbon fluoride based gas. It is also necessary to find out a condition which ensures compatibility between the two.

When electromagnetic wave is not radiated (magnetic field: OT), decomposition of etching gas does not proceed, and etching is performed to produce a forward tapered shape. If the magnetic field strength is increased, gas decomposition proceeds and a nearly vertical is formed. At the same time, etching rate increases, so the etching velocity ratio increases conversely. It drops suddenly when a condition to promote further decomposition is established.

As described above, decomposition of this carbon fluoride based gas can be controlled by changing the magnetic field, according to the present invention. The present invention makes it possible to optimize such etching characteristics as etching velocity ratio between silicon oxide film and silicon film, and etching shape.

Furthermore, optimization of the etching characteristics can be controlled by the magnetic field, independently of process conditions such as pressure, etching gas flow rate and radio frequency power. This allows process conditions to be determined by fine processing, processing velocity and such related factors, resulting in an expanded margin of processing.

Radio frequency power is applied to the stage electrode 3 from the bias power supply 17 through transformer 29. Radio frequency current passes through the substrate 15 and plasma, and flows to facing electrodes 2a and 2b. Since the transformer 29 is kept separated from the ground, almost all the radio frequency current lowing from the stage electrode 3 is fed to facing electrodes 2a and 2b, without going to any other places.

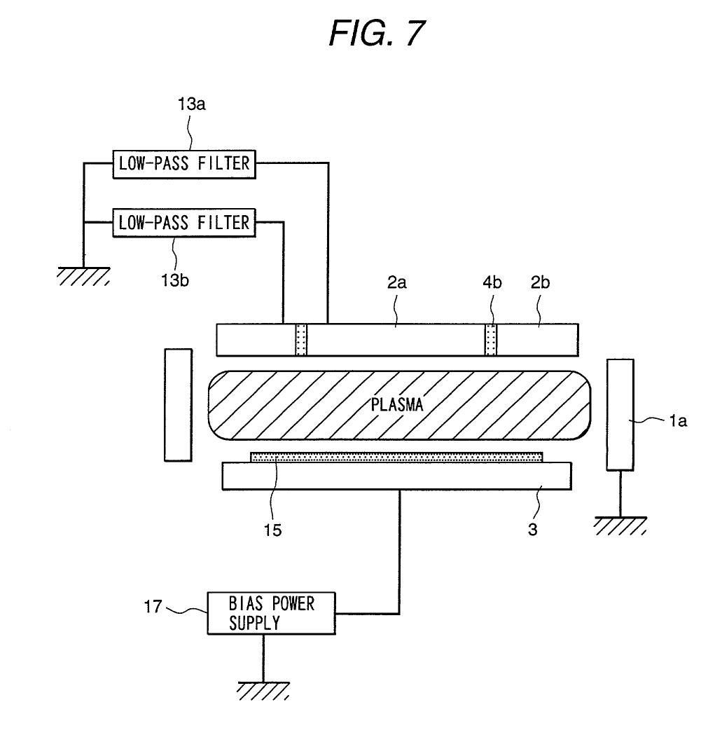

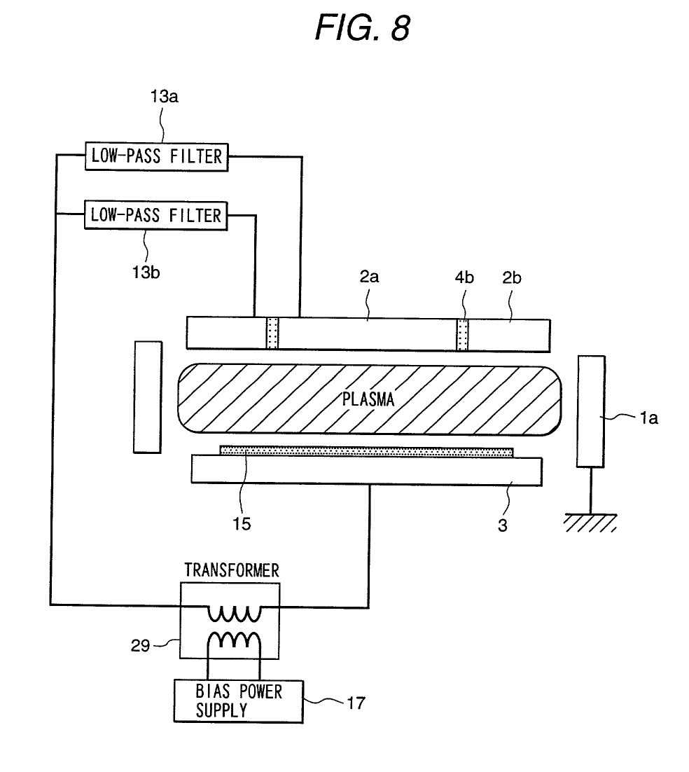

The radio frequency bias current path controlling the energy of ion applied ot this substrate 15 is formulate into a model, and is shown in FIG. 7 as a normal path. FIG. 8 shows the path of this Embodiment. The difference between the two will be discussed below.

In the normal arrangement, out of the outputs from bias power source 17 connected to the stage electrode 3 is connected to the ground, as shown in FIG. 7. The radio frequency voltage output terminal is connected to the stage electrode 3. Passing through substrate 15, radio frequency current is fed to the facing electrodes 2a and 2b and to the inner wall 1a of the process chamber through plasma. Passing through the ground, it goes back to the bias power supply 17.

On the outer periphery of stage electrode 3, radio frequency current can flow to both the facing electrode 2b and inner wall 1a of the process chamber. So current path impedance is reduced to facilitate flow of radio frequency current, and density of the radio frequency current flowing through the substrate 15 shows a distribution high on the outer periphery and low at the central portion. This is one of the biggest causes for changes of characteristics when the semiconductor device substrate is processed.

In this Embodiment as shown in FIG. 8, the output of the bias power supply 17 is kept separated from the ground through the transistor 29 and is connected to the stage electrode 3. A current circuit is provided in such a way that the current can go back to the transformer from facing electrodes 2a and 2b through low pass filters 13a and 13b.

If an arrangement is made to reduce capacitative component between the current circuit for the current to go back to the transformer and ground, the current flows from the stage electrode 3 to the inner wall la of the process chamber, and impedance of the path for the current to go back to the transformer is increased. Thus, radio frequency current flowing through this path is greatly reduced. Therefore, radio frequency current flowing from the stage electrode 3 mostly flows to the facing electrodes 2a and 2b.

As a result, parallel installation of stage electrode 3 and facing electrodes 2a and 2b makes radio frequency current distribution almost uniform. This leads to a substantial relief of the problem that electric characteristics of the semiconductor device are much changed by electrical influence during plasma processing.

Impedance of bias power supply 17 to frequency can be made variable by shifting the characteristics of low pass filters 13a and 13b with respect to frequency of bias power supply 17.

If the low pass filter 13a is set so that impedance is minimized and the impedance of low pass filter 13b is set to a value higher than that, radio frequency current passing through the substrate 15 will exhibit a distribution where current density is high at the central portion and is low on the outer periphery. If setting of the low pass filter impedance is reversed, distribution will show that current density is high on the outer periphery and low at central portion.

As described above, optimization of the impedance of low pass filters 13a and 13b allows more uniform control of self-bias potential distribution occurring to the substrate 15, and further reduces the changes in the electric characteristics of the semiconductor device due to plasma processing.

Furthermore, if low pass filters 13a and 13b are controlled by the drive motor and distribution control similarly to the variable capacitor 11, then control can be made to reach the optimum state where changes in electric characteristics of the semiconductor device do not occur with respect to changes of processing conditions and changes of the state during processing.

When etching is continued, a deposition film is formed on the inner wall surface of the process chamber 1. This film will be separated to produce dust. Since ion from plasma is applied to the facing electrodes 2a and 2b at an increased velocity by the radio frequency power to be applied, a deposition film does not stick to the surface of the electrode, and no dust is produced. When 400 kHz radio frequency power is supplied from the radio frequency power supply 18 to the inner wall surface 1a, radio frequency current flows to the inner wall surface 1b connected to the ground through plasma and the outer periphery of the stage electrode 3. Deposition film can be prevented from attaching onto the inner wall surface by accelerating entering the inner wall.

Covers 8a to 8d are made of silicon, and the effect differs according to the silicon resistance. The case of using a silicon having a high resistance has been mentioned in the Embodiment discussed above.

When a low-resistance silicon is used, displacement current flowing between the facing electrodes 2a and 2b does not flow through the insulator 4b due to a limited space of 0.2 mm between covers 8a to 8d. It flows mainly between covers 8b and 8c. Radio frequency displacement current flowing between the facing electrode 2b and process chamber 1a flows mainly between covers 8c and 8d.

When the space between covers is set inclined with respect to magnetic field, displacement current flows in the direction at a right angle to the inclined surface, and electromagnetic waves are radiated in the inclined direction of the space, as shown in the Figure.

A sheath is formed between the cover and plasma when plasma is generated, and electromagnetic waves radiated in an inclined direction with respect to magnetic field are divided into two component; a component which proceeds along the magnetic field in plasma, and a component which travels through the sheath.

Electromagnetic wave traveling through the sheath proceeds gradually in the direction of magnetic field, so electromagnetic wave exhibits a flat distribution as compared to the case where electromagnetic wave is radiated parallel with magnetic field. If this property is utilized, uniform plasma can be formed even when electromagnetic wave radiating portion is arranged in a single ring electrode structure. However, this does not allow electric control of plasma distribution.

Even when the electromagnetic wave radiating portion is made in a double ring electrode arrangement, there is an effect of improving distribution controllability, because flat distribution is ensured for both the plasma generated by electromagnetic wave from the electromagnetic wave radiating portion on the inner periphery and the plasma generated by electromagnetic wave from the electromagnetic wave radiating portion on the outer periphery.

Furthermore, covers 8a to 8d are split parts in the present Embodiment; however, it should not be understood that the present invention is limited only to them. FIG. 9 shows the structure of covers in another Embodiment. This cover 30 has quartz rings 32a and 32b embedded between silicon rings 31a to 31c.

Said cover 30 can be handled as one disk, and improves workability of replacement or the like.

The following describes the case of plasma CVD. Organic silane based gas including fluorine, and oxygen gas are mixed and supplied as process gas. Process gas is decomposed by plasma in the process chamber to form a silicon oxide film on substrate.

Silicon oxide film adheres not only on the substrate 15 but also on covers 8a to 8d on the surface of the facing electrode as well as inner wall surface 1a, etc. As described above, however, ion is applied to covers 8a to 8d on the surface of the facing electrode and inner wall surface 1a at an accelerated rate by application of radio frequency power. Silicon oxide film is removed by the effect assistance of this ion and fluorine radical generated from the fluorine contained in organic silane gas.

As described above, the first Embodiment of the present invention provides a plasma processing apparatus and processing method characterized by a wide range of controlling the electron energy state and by the capability of controlling the generation of radical species, independently of processing conditions and uniformity control.

It also provides a plasma processing apparatus and processing method comprising a uniformity control means ensuring compatibility of plasma uniformity with radical species control, ion energy control and improved ion directionality by generation of low pressure high density plasma, said means characterized by control capability independently of such processing conditions as plasma generation power and pressure.

It also provides a plasma processing apparatus and processing method comprising a means to reduce changes of electric characteristics of the semiconductor device due to electric influence during plasma processing, said means being capable of ensuring compatibility reduction of changes of electric characteristics of the semiconductor device due to electric influence during plasma processing with plasma uniformity control, radical species control, ion energy control and improved ion directionality due to generation of low pressure high density plasma; and said means characterized by control capability independently of such processing conditions as plasma generation power and pressure.

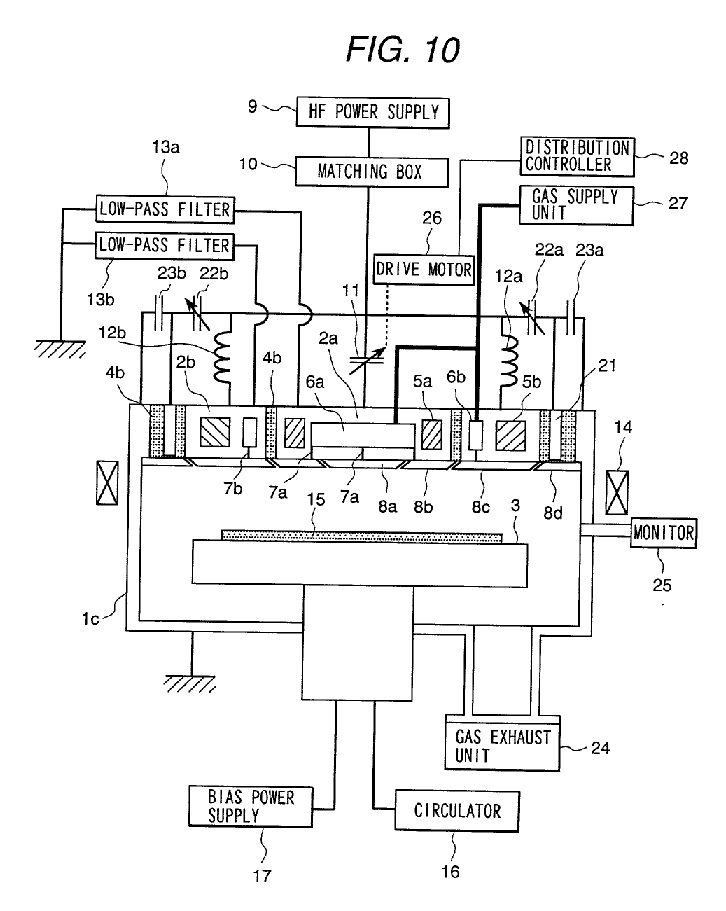

FIG. 10 is a schematic drawing representing a plasma processing apparatus as a second Embodiment according to the present invention.

The second Embodiment will be described mainly with regard to the differences from said first Embodiment, with the same description omitted.

The differences of the second Embodiment from the first one is that a ring block 21 is provided on the outer periphery of facing electrodes 2a and 2b. The ring block 21 is isolated from the insulator 4d, facing electrode 2b, process chamber 1c and cover 8d.

Inductors 12a and 12b and ring block 21 are connected with each other through variable capacitors 22a and 22b, and ring block 21 and process chamber 1c are connected with each other through capacitors 23a and 23b.

The following describes the process treatment in the second Embodiment:

Emission and control of electromagnetic waves from insulator 4b are the same as those described in reference to the first Embodiment. The resonance state of the resonant A circuit composed of inductors 12a and variable capacitor 22a and the resonant circuit composed of inductor 12b and variable capacitor 22b is controlled by variable capacitors 22a and 22b, thereby controlling radio frequency displacement current between the facing electrode: 2b and ring block 21 and distribution in the circumferential direction. This, electromagnetic waves from between the ring block 21 and facing electrode 2b are radiated in proportion to this radio frequency displacement current.

The second Embodiment provides the optimum plasma distribution since it enables both independent control of the emission of electromagnetic waves on the inner and outer peripheries of process chamber 1c, and control of distribution in the circumferential direction.

In FIGS. 3 to 5 described above, plasma distribution is controlled by density distribution 52, 54 and 56 of the plasma generated by electromagnetic wave radiated from the central portion. In the present Embodiment, density distribution 51 of the plasma generated by electromagnetic wave radiated the outer periphery can also be controlled. In addition, control distribution under axially symmetric conditions and in the circumferential direction can be controlled.

The following describes an example of wired film etching in the second Embodiment. Substrate 15 where aluminum film is formed on the silicon oxide film is installed on the stage electrode 3. After that, chlorine based etching gas is supplied into the process chamber 1c, and the pressure is set to 1 Pa. Then radio frequency power of 1000W is supplied to the facing electrodes 2a and 2b to generate plasma. Radio frequency power of 100W is applied to the stage electrode 3, and ion applied to the substrate 15 from plasma is accelerated by this radio frequency bias.

On the surface of the substrate 15, resist mask used for patterning is decomposed by plasma, and deposition film is formed from the decomposed gas or the like. The deposition film is removed by application of ion and the exposed aluminum film reacts with chlorine based radical species generated in plasma, thereby ensuring progress of etching.

The deposition film formed on the surface of substrate 15 is not formed uniformly. There is a greater volume of deposit at the central portion. So the volume of ion at the center must be increased to ensure uniform etching.

When aluminum etching has completed and underlying silicon oxide film is exposed, etching of silicon oxide film proceeds in proportion to the volume of ion. Under the same etching conditions as those of aluminum film, a greater amount of silicon oxide film at the central portion will be etched.

Therefore, during etching of aluminum film and silicon oxide film as an underlying film, plasma distribution must be subjected to adequate in-process control according to each condition.

In this second Embodiment, variable capacitors 11, 22a and 22b are designed as variable by means of a drive motor 26, distribution controller 28, similar drive mechanism and control mechanism. This allows plasma distribution to be controlled by the plasma processing apparatus control mechanism, similarly to such processing conditions as pressure and power.

Some processing conditions are set in the controller in the etching system. Processing pressure, radio frequency power to be applied, type and volume of etching gas supplied into the process chamber and the like are memorized under one setting conditions. Etching is carried out by a combination of some of these setting conditions. This combination is also memorized in the controller. The etching system start processing when the setup conditions and combination (normally called recipe) are specified.

In the present invention, a control program is designed to allow plasma uniformity as well as pressure and power to be incorporated into this setup condition, to ensure that variable capacitor capacity can be controlled by this specification.

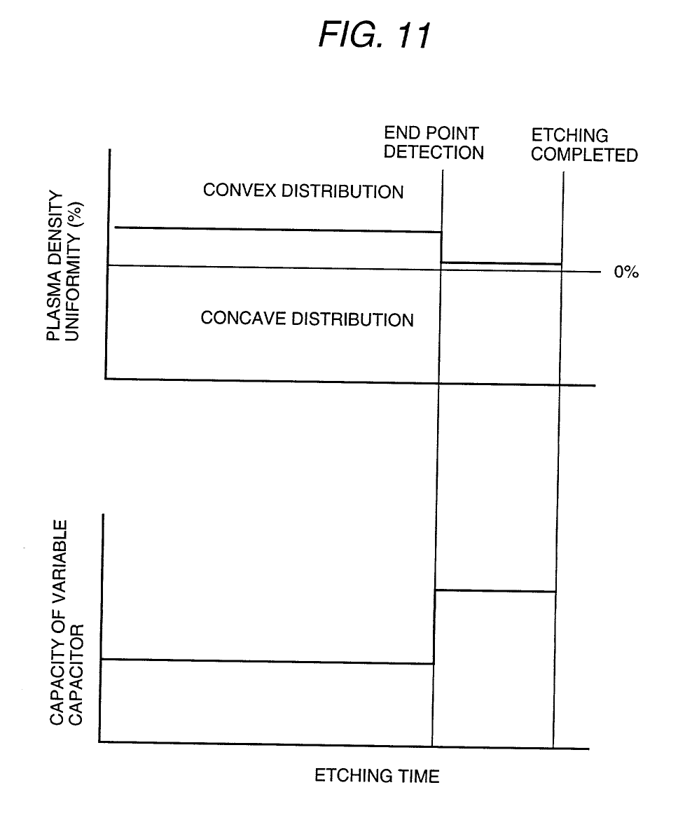

The processing procedures of etching with plasma uniformity incorporated in this condition will be described with reference to an example of aluminum film etching described above. FIG. 11 shows the relationship between the plasma uniformity control and elapse of time in this etching procedure.

Plasma distribution is controlled by detecting the point where aluminum film etching is changed to silicon oxide film etching, where the detection is made according to the result of monitoring the end point of etching with the monitor 25.

During etching of aluminum film, plasma density is set to convex distribution. Control is made as follows: When the end point of etching is detected by the monitor 25, the capacity of variable capacitor 11 is increased by the drive motor, thereby getting uniform plasma distribution. This state is maintained until the end of etching.

Aluminum film is not formed uniformly; film thickness has a distribution. To form fine patterns with high precision, it is necessary to provide a high precision control of over-etching time or the like after completion of etching. Etching of aluminum film must terminate simultaneously on all surfaces of substrate 15.

In the Embodiment according to the present invention, the thickness of the etched film is measured by a film thickness measuring means (not illustrated), and plasma distribution is controlled for each substrate by counting backward from the result of measuring the film thickness distribution, to ensure that etching is terminated simultaneously on all surfaces of the substrate.

In this control, from the data on the etched film input into the etching controller, calculation is made to obtain the etching rate and distribution which ensure that etching of the etched film is terminated simultaneously on all surfaces of the substrate. Then plasma density distribution required for etching rate is prepared. From the relationship between the capacitor capacity shown in FIG. 6 and plasma distribution, the capacity of variable capacitors 11, 22a and 22b is calculated, and plasma distribution is controlled by the distribution controller 28 and drive motor 26, thereby allowing etching to be carried out.

From the view point of electronic energy control, the second Embodiment has been described mainly regarding the discharge based plasma processing where the state of electron energy is controlled under capacitatively coupled discharge conditions where magnetic field is not applied, to electronic cyclotron resonant conditions where magnetic field is applied. Plasma distribution and gas decomposition can also be controlled by discharge where magnetic field is not used.

In the second Embodiment illustrated in FIG. 10, electromagnetic wave power applied to the central portion of the process chamber 1c is increased by increasing the displacement current flowing to the resonant circuit formed by variable capacitor 11 and inductors 12a and 12b. Then electromagnetic wave power is supplied to plasma as in the case of inductively coupled plasma. However, there is much reflection from plasma, and a great amount of radio frequency displacement current must be supplied than in the case where magnetic field is used.

Electromagnetic wave power radiated from the outer periphery can be controlled in the same way as that radiated from the central portion described above by increasing displacement current flowing to the resonant circuit formed by variable capacitors 22a and 22b and inductors 12a and 12b.

This allows a double ring plasma on the central portion and outer periphery to be formed in the process chamber 1c by inductive coupling. Uniform plasma can be formed on the large-diameter substrate 15. Furthermore, plasma distribution ranging from convex distribution to concave distribution can be controlled by controlling each of displacement current at the central portion and radio frequency displacement current on the outer periphery.

When this magnetic field is not used, energy is supplied intensively to plasma in the vicinity where electromagnetic wave is radiated. So electronic energy is increased to a high level to facilitate decomposition of process gas.

Thus, the following conditions can be controlled by the magnetic field formed by variable capacitors 11, 22a and 22b and coil 14 as shown in the present Embodiment; (1) a condition where radio frequency displacement current is reduced, and discharge is mostly carried out under the capacitatively coupled condition, (2) a condition where radio frequency displacement current is increased and locally powerful plasma is formed to promote decomposition of process gas, and (3) a condition where the travel of electromagnetic wave in plasma is facilitated by formation of magnetic field, and slow decomposition of process gas provided by supply of energy from electromagnetic wave to plasma in the entire process chamber.

The second Embodiment provides a plasma processing apparatus and processing method characterized by a wide control range of the state of electron energy as in the case of the first Embodiment, and by the capability of controlling the generation of radical species, independently of processing conditions and uniformity control.

In the Embodiment according to the present invention described above, mainly the etching and plasma CVD have been described. However, it should not be understood that the present invention is limited only to them. It is clear that the present invention is applicable to processing using plasma such as plasma polymerization and sputtering.

In the above-mentioned Embodiment according to the present invention, the frequency of the radio frequency power supply for plasma generation has been described for the case where it is 100 MHz. As described in the first Embodiment, the similar effect can be obtained within the range from 200 MHz to 10 MHz.

It is also possible to store in the memory means the processing procedure for the control of above-mentioned plasma processing distribution, and to control plasma distribution by means of a control means according to the stored processing procedure, thereby forming plasma processing.

The present invention allows the state electron energy to be controlled independently in the plasma processing apparatus. This makes it possible to control generation of radical species, and to ensures compatibility of the characteristics, for example, between etching of high selectivity and high precision, high-speed etching, or film quality and film formation speed, where the compatibility of such characteristics has been difficult to be ensured in the prior art.

Furthermore, plasma density distribution can be controlled without changing hardware configuration, and minute-pattern high-precision etching and uniform film formation are possible on all surfaces of the large-diameter substrate.

Plasma distribution can also be controlled during plasma processing, independently of process conditions. Higher precision etching and more uniform film formation can be ensured by controlling plasma distribution in conformity to the progress of plasma processing.

In the present invention, electromagnetic wave is radiated by the control of radio frequency displacement current. According to this method, the space for radiating the electromagnetic wave can be made as narrow as about 0.2 mm, as described in the Embodiment. This method is the same as the inductively RF coupled method in that electromagnetic wave is radiated, but the space for radiating the electromagnetic wave cannot be reduced to that extent according to the inductively RF coupled method. Thus, the present invention has the effect of allowing more stable processing than prior art methods, without being affected by deposition film attached on the wave radiating portion.

The present invention further reduces occurrence of changes of electric characteristics in semiconductor devices by plasma processing, and provides an effect of improving yields in semiconductor device production.

This has ensured a high performance in processing of semiconductor devices and liquid crystal display devices, and provides the effect of permitting higher performance device production. Namely, the present invention realizes a plasma processing apparatus and processing method which allows independent optimization of each of processing conditions, uniformity control, radical species generation control and prevention of changes in electric characteristics.

The present invention provides the effect of using wide ranging processing conditions, without processing conditions such as pressure and power being restricted by the needs for uniformity or prevention of changes in electric characteristics.

What is claimed is:

1. A plasma processing apparatus to provide plasma processing of a substrate by plasma, said plasma processing apparatus comprising a plasma processing gas supply means, an exhaust means in a plasma process chamber, and a plasma generating means; said plasma generating means further comprises
a capacitatively coupled discharge means consisting of mutually isolated multiple conductors,
an electromagnetic wave radiating means to cause radio frequency displacement current to flow between said conductors and to emit electromagnetic wave, and
a magnetic field forming means;
wherein said electromagnetic wave radiating means further comprises an radiated electromagnetic wave power control means to control the radiated electromagnetic wave power through radio frequency displacement current control means forming a resonant circuit.

2. A plasma processing apparatus comprising a plasma processing gas supply means, an exhaust means in a plasma process chamber, a plasma generating means, and a means to process plasma using the generated plasma; said plasma generating means further comprises;
a capacitatively coupled discharge means consisting of mutually isolated multiple conductors and
an electromagnetic wave radiating means to cause radio frequency displacement current to flow between said conductors and to emit electromagnetic wave;
wherein said electromagnetic wave radiating means further comprising an radiated electromagnetic wave power control means to control radiated electromagnetic wave power using the radio frequency displacement current control means forming a resonant circuit.

3. A plasma processing apparatus according to claim 1 or 2 further characterized by comprising a means to store the processing procedure to control distribution during plasma processing and to control plasma distribution according to the processing procedure stored in said memory means.

4. A plasma processing method which supplies plasma processing gas into a plasma process chamber, sets the pressure inside said plasma process chamber to the preset value, and generates plasma by capacitatively coupled discharge, emission of electromagnetic wave by radio frequency displacement current and formation of magnetic field, thereby processing a substrate;
said plasma processing method comprises steps of;
controlling radiated electromagnetic wave power by the radio frequency displacement current control means forming a resonant circuit, and
processing a substrate while plasma distribution is controlled during plasma processing.

5. A plasma processing method which supplies plasma processing gas into a plasma process chamber, sets the pressure inside said plasma process chamber to the preset value, and generates plasma by capacitatively coupled discharge, emission of electromagnetic wave by radio frequency displacement current and formation of magnetic field, thereby processing a substrate;
said plasma processing method comprises steps of;
setting displacement current frequency within the range from 10 MHz to 200 MHz,
controlling radiated electromagnetic wave power by the radio frequency displacement current control means forming the resonant circuit,
controlling plasma distribution during plasma processing, and
processing a substrate at the magnetic field strength within the range from from 2×10⁻⁴T to 10⁻²T.

6. A plasma processing method according to claim 4 or 5 further characterized in that plasma distribution is controlled to ensure that plasma processing of said substrate is completed uniformly for every plasma processing or during plasma processing according to uneven conditions of the substrate to be processed.

7. A plasma processing system comprising;
a plasma processing gas supply means,
an exhaust means in a plasma process chamber,
a plasma generating means,
a means to send RF current to a substrate to be processed, and
a means to process plasma using the generated plasma;
said plasma processing system characterized in that a RF bias circuit to send RF current to the substrate to be processed is suspended with respect to the ground.

8. A plasma processing system comprising;
a plasma processing gas supply means,
an exhaust means in a plasma process chamber,
a plasma generating means, and
a means to send RF current to a substrate to be processed, and
a means to process plasma using the generated plasma;
said means to send RF current to a substrate to be processed further characterized in that;
multiple RF current conducting means are installed at the position opposite to the position where the substrate to be processed is mounted, and
said multiple RF current conducting means are provided with a means to control a RF current ratio by each RF current flowing from the substrate to be processed.
